(19) United States
(12) Patent Application Publication
(10) Pub. No.: US 2026/0184964 A1
(43) Pub. Date: Jul. 2, 2026

(54) POLISHING LIQUID AND POLISHING METHOD

(71) Applicant: Resonac Corporation, Tokyo (JP)

(72) Inventors: Daisuke IIKURA, Minato-ku, Tokyo (JP); Mai HAGIWARA, Minato-ku, Tokyo (JP); Shintaro FUKUDA, Minato-ku, Tokyo (JP)

(21) Appl. No.: 18/859,751

(22) PCT Filed: Sep. 10, 2024
(86) PCT No.: PCT/JP2024/032400

§ 371 Date: Oct. 24, 2024

(30) Foreign Application Priority Data
Sep. 12, 2023 (WO) PCT/JP2023/033222

(51) Int. Cl. C09G 1/02; B24B 37/04; H10P 52/40

(52) U.S. Cl. CPC C09G 1/02; B24B 37/044; H10P 52/407

(57) ABSTRACT

A polishing liquid contains abrasive grains and an acid component, in which the acid component contains a compound (excluding sulfuric acid and a salt thereof) having at least one selected from the group consisting of a sulfo group and a sulfonate group, and a pH is more than 4.5. A polishing method includes a step of polishing a surface to be polished using the polishing liquid.

### TECHNICAL FIELD

The present disclosure relates to a polishing liquid, a polishing method, and the like.

### BACKGROUND ART

In recent years, processing techniques for increasing density and miniaturization are becoming ever more important in manufacturing steps for semiconductor elements. CMP (chemical mechanical polishing) technique that is one of processing techniques has become an essential technique in manufacturing steps for semiconductor elements, for the formation of a shallow trench isolation (hereinafter, referred to as “STI”), flattening of pre-metal insulating materials or interlayer insulating materials, formation of plugs or embedded metal wirings, or the like.

As a polishing liquid most frequently used, for example, a silica-based polishing liquid containing silica (silicon oxide) particles such as fumed silica or colloidal silica as abrasive grains is exemplified. The silica-based polishing liquid is characterized by being high in general versatility, and can polish broad types of materials irrespective of insulating materials and conductive materials by appropriately selecting an abrasive grain content, a pH, an additive, or the like.

Meanwhile, as a polishing liquid mainly used for insulating materials such as silicon oxide, a demand for a polishing liquid containing cerium compound particles as abrasive grains is also increasing. For example, a cerium oxide-based polishing liquid containing cerium oxide particles as abrasive grains can polish silicon oxide at a high rate even when the abrasive grain content is lower than that in the silica-based polishing liquid (for example, see Patent Literatures 1 and 2 described below).

In recent years, in the manufacturing steps for semiconductor elements, it is required to achieve further micronization of wiring, and polishing scratches generated at the time of polishing are becoming problematic. That is, when polishing is performed using a conventional cerium oxide-based polishing liquid, even if minute polishing scratches are generated, there has been no problem as long as the sizes of the polishing scratches are smaller than conventional wiring widths; however, in a case where it is directed to achieve further micronization of the wiring, even minute polishing scratches become problematic.

With regard to this problem, an investigation has been conducted on polishing liquids that use particles of cerium hydroxide (for example, see Patent Literatures 3 to 5 described below). Furthermore, methods for producing particles of cerium hydroxide have also been investigated (for example, see Patent Literatures 6 and 7 described below).

### CITATION LIST

### Patent Literature

Patent Literature 1: Japanese Unexamined Patent Publication No. H10-106994
Patent Literature 2: Japanese Unexamined Patent Publication No. H08-022970
Patent Literature 3: International Publication WO 2002/067309
Patent Literature 4: International Publication WO 2012/070541
Patent Literature 5: International Publication WO 2012/070542
Patent Literature 6: Japanese Unexamined Patent Publication No. 2006-249129
Patent Literature 7: International Publication WO 2012/070544

### SUMMARY OF INVENTION

### Technical Problem

In semiconductor elements in recent years, miniaturization has been further accelerated, and thinning has progressed along with the reduction in wiring width. Along with this, in the CMP step or the like for formation of STI, it is necessary to polish the insulating member while suppressing excessive polishing of the stopper disposed on the convex portion of the substrate having a concavo-convex pattern. From such a viewpoint, it is required for the polishing liquid to obtain excellent polishing selectivity of an insulating material with respect to a stopper material (polishing rate ratio: the polishing rate for an insulating material/the polishing rate for a stopper material), and for example, it is required to obtain excellent polishing selectivity of silicon oxide with respect to silicon nitride (polishing rate ratio: the polishing rate for silicon oxide/the polishing rate of silicon nitride).

An object of an aspect of the present disclosure is to provide a polishing liquid capable of obtaining excellent polishing selectivity of silicon oxide with respect to silicon nitride. Furthermore, an object of another aspect of the present disclosure is to provide a polishing method using this polishing liquid.

### Solution to Problem

One aspect of the present disclosure includes the following [1] to [11].
[1] A polishing liquid containing: abrasive grains; and an acid component, in which
   the acid component contains a compound (excluding sulfuric acid and a salt thereof) having at least one selected from the group consisting of a sulfo group and a sulfonate group, and
   a pH is more than 4.5.
[2] The polishing liquid according to [1], in which the abrasive grains contain a cerium hydroxide.
[3] The polishing liquid according to [1] or [2], in which the acid component contains an aromatic compound having at least one selected from the group consisting of a sulfo group and a sulfonate group. [4] The polishing liquid according to any one of [1] to [3], in which the acid component contains a compound having no amino group.
[5] The polishing liquid according to any one of [1] to [4], in which the acid component contains an aminosulfonic acid compound.
[6] The polishing liquid according to any one of [1] to [5], in which the acid component contains at least one selected from the group consisting of sulfanilic acid and a salt thereof.
[7] The polishing liquid according to any one of [1] to [6], in which the content of the acid component is more than 0.2 mass % based on the total mass of the polishing liquid.
[8] The polishing liquid according to any one of [1] to [7], further containing a non-ionic polymer.
[9] The polishing liquid according to [8], in which the non-ionic polymer contains a glycerin-based polymer.
[10] The polishing liquid according to any one of [1] to [9], further containing a base component.
[11] The polishing liquid according to any one of [1] to [10], which is used for polishing a surface to be polished containing silicon oxide and silicon nitride.
[12] A polishing method including a step of polishing a surface to be polished using the polishing liquid according to any one of [1] to [11].
[13] The polishing method according to [12], in which the surface to be polished contains silicon oxide and silicon nitride.
[14] A method for manufacturing a component, the method including a step of obtaining the component using a member to be polished that has been polished by the polishing method according to [12] or [13].

### Advantageous Effects of Invention

According to an aspect of the present disclosure, it is possible to provide a polishing liquid capable of obtaining excellent polishing selectivity of silicon oxide with respect to silicon nitride. Furthermore, according to another aspect of the present disclosure, it is possible to provide a polishing method using this polishing liquid.

### DESCRIPTION OF EMBODIMENTS

Hereinafter, an embodiment of the present disclosure will be described in detail.

### Definition

In the present specification, the term “polishing liquid” is defined as a composition to be brought into contact with a surface to be polished, at the time of polishing. The term “polishing liquid” itself does not limit any components contained in the polishing liquid. As described later, a polishing liquid of the present embodiment can contain abrasive grains. The abrasive grains are also referred to as “polishing particles” (abrasive particle), but are referred to as “abrasive grains” in the present specification. The abrasive grains are generally solid particles, and it is considered that a subject to be removed is removed by a mechanical action of the abrasive grains and a chemical action of the abrasive grains (mainly, the surface of the abrasive grains) at the time of polishing, but the polishing mechanism is not limited thereto. “Polishing rate” means a rate at which the material is removed per unit time (Removal Rate).

A numerical range that has been indicated by use of “to” indicates the range that includes the numerical values which are described before and after “to”, as the minimum value and the maximum value, respectively. “A or more” in the numerical range means A and a range of more than A. “A or less” in the numerical range means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical value range may be replaced with the value shown in the examples. Materials listed as examples in the present specification may be used singly or in combinations of two or more, unless otherwise specifically indicated. When a plurality of substances corresponding to each component exist in the composition, the content of each component in the composition means the total amount of the plurality of substances that exist in the composition, unless otherwise specified. “A or B” may include either one of A and B, and may also include both of A and B. The term “film” includes a structure having a shape which is formed on a part, in addition to a structure having a shape which is formed on the whole surface, when the film has been observed as a plan view. The term “step” includes not only an independent step but also a step by which an intended action of the step is achieved, though the step cannot be clearly distinguished from other steps.

### <Polishing Liquid>

The polishing liquid according to the present embodiment contains abrasive grains and an acid component, and has a pH of more than 4.5. The acid component contains a compound (excluding sulfuric acid and a salt thereof) having at least one selected from the group consisting of a sulfo group and a sulfonate group (hereinafter, such a compound is also referred to as an “acid component A”).

The polishing liquid according to the present embodiment can be used as a CMP polishing liquid. The polishing liquid according to the present embodiment can be used for polishing a surface to be polished (exposed surface) containing silicon oxide and silicon nitride, and can be used for polishing the surface to be polished containing silicon oxide and silicon nitride to selectively remove silicon oxide with respect to silicon nitride. The polishing liquid according to the present embodiment can be used for polishing a surface to be polished (exposed surface) containing silicon oxide and silicon carbonitride, and can also be used for polishing the surface to be polished containing silicon oxide and silicon carbonitride to selectively remove silicon oxide with respect to silicon carbonitride.

According to the polishing liquid of the present embodiment, it is possible to selectively remove silicon oxide with respect to silicon nitride and to obtain excellent polishing selectivity of silicon oxide with respect to silicon nitride (polishing rate ratio: the polishing rate for silicon oxide/the polishing rate for silicon nitride). According to the polishing liquid of the present embodiment, it is possible to obtain a polishing rate ratio of 2.5 or more as the polishing rate ratio of silicon oxide with respect to silicon nitride.

A reason why the above-described effects are exhibited is not necessarily clear, but the present inventors infer the reason as follows. That is, when the pH of the polishing liquid is more than 4.5, by containing a compound (excluding sulfuric acid and a salt thereof) having at least one selected from the group consisting of a sulfo group and a sulfonate group as an acid component, the sulfo group and the sulfonate group of the compound are selectively adsorbed to silicon nitride. As a result, polishing of silicon nitride is significantly suppressed without suppressing polishing of silicon oxide. From the above reason, according to the polishing liquid according to the present embodiment, it is possible to obtain excellent polishing selectivity of silicon oxide with respect to silicon nitride. Note that the reason why the effect is exhibited is not limited to the content.

A polishing rate ratio of silicon oxide with respect to silicon nitride may be 20 or more, 30 or more, 40 or more, 50 or more, 80 or more, 100 or more, 200 or more, 300 or more, 400 or more, or 500 or more. The polishing rate ratio of silicon oxide with respect to silicon nitride may be 5000 or less, 4500 or less, 4000 or less, 3500 or less, or 3000 or less.

According to the polishing liquid according to the present embodiment, for example, in an evaluation method of Examples described later, it is possible to obtain 10 Å/min or more as a polishing rate of silicon oxide, and the polishing rate of silicon oxide may be 100 Å/min or more, 1000 Å/min or more, 1400 Å/min or more, 1600 Å/min or more, 1800 Å/min or more, 1900 Å/min or more, 2000 Å/min or more, 2100 Å/min or more, 2200 Å/min or more, 2300 Å/min or more, or 2400 Å/min or more.

According to the polishing liquid according to the present embodiment, for example, in the evaluation method of Examples described later, it is possible to obtain 600 Å/min or less as a polishing rate of silicon nitride, and the polishing rate of silicon nitride may be 550 Å/min or less, 500 Å/min or less, 450 Å/min or less, 400 Å/min or less, 350 Å/min or less, 300 Å/min or less, 250 Å/min or less, 200 Å/min or less, 150 Å/min or less, 100 Å/min or less, 50 Å/min or less, 30 Å/min or less, or 10 Å/min or less.

### (Abrasive Grains)

Examples of a constituent material of the abrasive grains include: inorganic substances such as abrasive grains containing a hydroxide of a tetravalent metal element such as cerium, silica, alumina, ceria (cerium oxide), titania, zirconia, germania, and silicon carbide; organic substances such as polystyrene, polyacrylic acid, and polyvinyl chloride; and modified products thereof. The “hydroxide of a tetravalent metal element” is a compound containing a tetravalent metal ion (M⁴⁺) and at least one hydroxide ion (OH⁻). The hydroxide of a tetravalent metal element may contain an anion other than a hydroxide ion (for example, a nitrate ion NO₃⁻ and a sulfate ion SO₄²⁻). For example, the hydroxide of a tetravalent metal element may contain an anion (for example, a nitrate ion NO₃⁻ and a sulfate ion SO₄²⁻) bonded to the tetravalent metal element. The abrasive grains may have hydrated water. As the abrasive grains containing a hydroxide of a tetravalent metal element, for example, for example, composite particles containing a hydroxide of a tetravalent metal element and silica can also be used.

The abrasive grains containing a hydroxide of a tetravalent metal element have higher reactivity with silicon oxide which is an insulating material than abrasive grains made of silica, ceria, or the like, and can polish silicon oxide at a high polishing rate. In addition, according to the abrasive grains containing a hydroxide of a tetravalent metal element, it is easy to suppress flaws on a surface to be polished.

The hydroxide of a tetravalent metal element may contain at least one selected from the group consisting of a hydroxide of a rare earth metal element and a hydroxide of zirconium, and may contain a hydroxide of a rare earth metal element from a viewpoint of easily obtaining excellent polishing selectivity of silicon oxide with respect to silicon nitride. Examples of a rare earth metal element which can be tetravalent include lanthanoids such as cerium, praseodymium, and terbium, and in particular, the rare earth metal element may be a lanthanoid, and may be cerium from a viewpoint of easily improving a polishing rate of an insulating material (silicon oxide or the like). In other words, the abrasive grains may contain a cerium hydroxide (a compound having a hydroxy group bonded to a cerium atom) as a hydroxide of a tetravalent metal element. A hydroxide of a rare earth metal element and a hydroxide of zirconium may be used in combination, or two or more types may be selected from the hydroxides of rare earth metal elements to be used.

The abrasive grains may contain cerium-based particles (particles containing a cerium compound) from a viewpoint of easily obtaining excellent polishing selectivity of silicon oxide with respect to silicon nitride. Examples of a cerium compound (a compound containing cerium) of the cerium-based particles include cerium hydroxide, cerium oxide, ammonium cerium nitrate, cerium acetate, cerium sulfate hydrate, cerium bromate, cerium bromide, cerium chloride, cerium oxalate, cerium nitrate, and cerium carbonate. The cerium compound may contain tetravalent cerium or trivalent cerium. The cerium-based particles may have hydrated water. The cerium-based particles may contain at least one selected from the group consisting of a cerium hydroxide and a cerium oxide, may contain a cerium hydroxide, may contain at least one selected from the group consisting of cerium hydroxide particles (particles containing cerium hydroxide) and cerium oxide particles (particles containing cerium oxide), and may contain cerium hydroxide particles from a viewpoint of easily obtaining excellent polishing selectivity of silicon oxide with respect to silicon nitride.

In the abrasive grains containing a hydroxide of a tetravalent metal element, the content of the hydroxide of a tetravalent metal element may be 50 mass % or more, more than 50 mass %, 55 mass % or more, 60 mass % or more, 65 mass % or more, 70 mass % or more, or 75 mass % or more based on the entire abrasive grains (the entire abrasive grains contained in the polishing liquid). The abrasive grains may be substantially composed of a hydroxide of a tetravalent metal element (substantially 100 mass % of the abrasive grains may be particles of a hydroxide of a tetravalent metal element) from a viewpoint of easy preparation of the polishing liquid and further excellent polishing characteristics. The content of the cerium hydroxide in the abrasive grains may be in the above-described range.

An average particle diameter of the abrasive grains may be 0.1 nm or more, 0.5 nm or more, 1 nm or more, 2 nm or more, 3 nm or more, 5 nm or more, 10 nm or more, or 12 nm or more from a viewpoint of easily improving a polishing rate of an insulating material (silicon oxide or the like). The average particle diameter of the abrasive grains may be 100 nm or less, 50 nm or less, 30 nm or less, 20 nm or less, 15 nm or less, or 12 nm or less from a viewpoint of easily suppressing flaws on a surface to be polished. The average particle diameter of the abrasive grains may be 0.1 to 100 nm from these viewpoints.

The “average particle diameter” of the abrasive grains means an average secondary particle diameter of the abrasive grains in the polishing liquid. The average particle diameter of the abrasive grains can be measured using a light diffraction/scattering type particle size distribution meter (for example, trade name: DelsaMax PRO manufactured by Beckman Coulter Inc.). In the measurement method using trade name: DelsaMax PRO manufactured by Beckman Coulter, Inc., specifically, for example, about 0.5 mL (L represents “liter”. The same applies hereinafter) of the polishing liquid is put in a measurement cell of 12.5 mm×12.5 mm×45 mm (height), and then the cell is disposed in the device. A refractive index and viscosity of measurement sample information are set to 1.333 and 0.887 mPa·s, respectively, measurement is performed at 25° C., and a value displayed as a unimodal size mean (cumulant diameter) can be adopted as the average particle diameter of the abrasive grains.

A zeta potential of the abrasive grains in the polishing liquid may be positive (more than 0 mV) from a viewpoint of easily obtaining excellent polishing selectivity of silicon oxide with respect to silicon nitride. The zeta potential (ζ [mV]) can be measured using a zeta potential measuring device (for example, DelsaNano C (device name) manufactured by Beckman Coulter Inc.). The zeta potential of the abrasive grains in the polishing liquid can be obtained, for example, by putting the polishing liquid in a concentration cell unit (a cell for a high concentration sample) for the zeta potential measuring device and measuring the zeta potential.

The content of the abrasive grains may be in the following range based on the total mass of the polishing liquid from a viewpoint of easily obtaining excellent polishing selectivity of silicon oxide with respect to silicon nitride. The content of the abrasive grains may be 0.001 mass % or more, 0.005 mass % or more, 0.008 mass % or more, 0.01 mass % or more, more than 0.01 mass %, 0.03 mass % or more, 0.04 mass % or more, or 0.05 mass % or more. The content of the abrasive grains may be 10 mass % or less, 5 mass % or less, 1 mass % or less, less than 1 mass %, 0.5 mass % or less, 0.3 mass % or less, 0.1 mass % or less, less than 0.1 mass %, 0.08 mass % or less, 0.07 mass % or less, 0.06 mass % or less, or 0.05 mass % or less. The content of the abrasive grains may be 0.001 to 10 mass % from these viewpoints. The content of the cerium hydroxide may be in the above-described range from a similar viewpoint.

### (Additive)

The polishing liquid of the present embodiment contains an additive. The “additive” refers to a substance that is contained in the polishing liquid in addition to the abrasive grains and water.

### [Acid Component A]

The polishing liquid according to the present embodiment contains a compound (acid component A) having at least one selected from the group consisting of a sulfo group and a sulfonate group (a functional group in which a hydrogen atom of a sulfo group is replaced with a metal atom (a sodium atom, a potassium atom, or the like) as an acid component. By using the acid component A, it is possible to obtain excellent polishing selectivity of silicon oxide with respect to silicon nitride while preventing aggregation of the abrasive grains and the like. The acid component A does not contain sulfuric acid and a salt thereof.

The number of sulfo groups and sulfonate groups included in the acid component A may be 5 or less, 4 or less, 3 or less, 2 or less, or 1 from a viewpoint of easily obtaining excellent polishing selectivity of silicon oxide with respect to silicon nitride.

The acid component A may have a functional group other than a sulfo group and a sulfonate group. The acid component A may further have, for example, at least one selected from the group consisting of an amino group, a carboxyl group, and a carboxylate group. The acid component A does not have to have an amino group from a viewpoint of easily suppressing a polishing rate of silicon nitride.

The number of amino groups included in the acid component A may be 5 or less, 4 or less, 3 or less, or 2 or less from a viewpoint of easily obtaining excellent polishing selectivity of silicon oxide with respect to silicon nitride.

The acid component A may contain an organic acid component (an organic acid and an organic acid derivative) or may contain an aromatic compound from a viewpoint of easily obtaining excellent polishing selectivity of silicon oxide with respect to silicon nitride. The acid component A is an aromatic compound, whereby an aromatic ring is adsorbed to silicon nitride, and excellent polishing selectivity of silicon oxide with respect to silicon nitride is easily obtained. The aromatic ring may be a monocyclic ring or a polycyclic ring. The aromatic ring may be at least one selected from the group consisting of a benzene ring, a naphthalene ring, a pyridine ring, and an isoquinoline ring.

When the acid component A contains an organic acid component, the number of carbon atoms of the organic acid component may be 2 or more, 3 or more, 4 or more, or 5 or more from a viewpoint of easily obtaining excellent polishing selectivity of silicon oxide with respect to silicon nitride. The number of carbon atoms in the organic acid component may be 12 or less, 11 or less, 10 or less, or 9 or less.

Examples of the aromatic compound include: an aromatic aminosulfonic acid such as an aminobenzenesulfonic acid (sulfanilic acid (also referred to as 4-aminobenzenesulfonic acid), methanilic acid (also referred to as 3-aminobenzenesulfonic acid), orthanilic acid (also referred to as 2-aminobenzenesulfonic acid), 2,4-diaminobenzenesulfonic acid, 3,4-diaminobenzenesulfonic acid, 3,4-diaminobenzenesulfonic acid, aminonaphthalenesulfonic acid, or 1,3-phenylenediamine-4-sulfonic acid; and an aromatic sulfonic acid such as benzenesulfonic acid, dimethylbenzenesulfonic acid, pyridinesulfonic acid, or isoquinoline-5-sulfonic acid. The acid component A may contain an aromatic compound having at least one selected from the group consisting of a sulfo group and a sulfonate group, and may contain an aromatic compound having at least one selected from the group consisting of a sulfo group and a sulfonate group and an amino group (an aromatic aminosulfonic acid and a salt thereof).

The acid component A may contain at least one aminosulfonic acid compound selected from the group consisting of aminosulfonic acid and an aminosulfonate from a viewpoint of easily obtaining excellent polishing selectivity of silicon oxide with respect to silicon nitride. The aminosulfonic acid compound has an amino group as a cation part, and has a sulfonic acid group or a sulfonate group as an anion part. Examples of the aminosulfonic acid compound include an aromatic aminosulfonic acid, an aliphatic aminosulfonic acid, sulfamic acid, and salts thereof.

Examples of the aromatic aminosulfonic acid include aminobenzenesulfonic acid (sulfanilic acid (also referred to as 4-aminobenzenesulfonic acid), methanylic acid (also referred to as 3-aminobenzenesulfonic acid), alternylic acid (also referred to as 2-aminobenzenesulfonic acid), 2,4-diaminobenzenesulfonic acid, 3,4-diaminobenzenesulfonic acid, 3,4-diaminobenzenesulfonic acid, aminonaphthalenesulfonic acid, and 1,3-phenylenediamine-4-sulfonic acid.

Examples of the aliphatic aminosulfonic acid include an aminomethanesulfonic acid, an aminoethanesulfonic acid (for example, 1-aminoethanesulfonic acid and 2-aminoethanesulfonic acid (also referred to as taurine)), and an aminopropanesulfonic acid (for example, 1-aminopropane-2-sulfonic acid and 2-aminopropane-1-sulfonic acid).

The acid component A may contain at least one selected from the group consisting of sulfanilic acid, sulfamic acid, benzenesulfonic acid, dimethylbenzenesulfonic acid, pyridinesulfonic acid, isoquinoline-5-sulfonic acid, and salts thereof from a viewpoint of easily obtaining excellent polishing selectivity of silicon oxide with respect to silicon nitride.

The content of the acid component A may be in the following range based on the total mass of the polishing liquid from a viewpoint of easily obtaining excellent polishing selectivity of silicon oxide with respect to silicon nitride. The content of the acid component A may be 0.01 mass % or more, 0.03 mass % or more, 0.05 mass % or more, more than 0.05 mass %, 0.08 mass % or more, 0.1 mass % or more, more than 0.1 mass %, 0.12 mass % or more, 0.14 mass % or more, 0.15 mass % or more, or 0.16 mass % or more. The content of the acid component A may be 10 mass % or less, 5 mass % or less, 3 mass % or less, 1 mass % or less, less than 1 mass %, 0.8 mass % or less, 0.6 mass % or less, 0.5 mass % or less, less than 0.5 mass %, 0.4 mass % or less, or 0.35 mass % or less. The content of the acid component A may be 0.01 to 10 mass % from these viewpoints. The content of the acid component A may be 0.2 mass % or more, more than 0.2 mass %, 0.22 mass % or more, 0.24 mass % or more, 0.26 mass % or more, 0.28 mass % or more, 0.3 mass % or more, or 0.32 mass % or more.

The content of the acid component A in the acid components contained in the polishing liquid (based on the total mass of the acid components), the content of an aromatic aminosulfonic acid in the acid components contained in the polishing liquid (based on the total mass of the acid components), and/or the content of an aromatic aminosulfonic acid in the acid component A (based on the total mass of the acid component A) may be 80 mass % or more, 90 mass % or more, 95 mass % or more, 98 mass % or more, or 99 mass % or more from a viewpoint of easily obtaining excellent polishing selectivity of silicon oxide with respect to silicon nitride. The acid components contained in the polishing liquid may be substantially composed of the acid component A (substantially 100 mass % of the acid components contained in the polishing liquid may be the acid component A). The acid components contained in the polishing liquid may be substantially composed of an aromatic aminosulfonic acid (substantially 100 mass % of the acid components contained in the polishing liquid may be an aromatic aminosulfonic acid). The acid component A may be substantially composed of an aromatic aminosulfonic acid (substantially 100 mass % of the acid component A may be an aromatic aminosulfonic acid).

A mass ratio of the content of the acid component A to the content of the abrasive grains (content of acid component A/content of abrasive grains) may be in the following range from a viewpoint of easily obtaining excellent polishing selectivity of silicon oxide with respect to silicon nitride. The mass ratio may be 20 or less, 15 or less, 12 or less, 10 or less, 9 or less, 8 or less, 7.5 or less, 7 or less, or 6.5 or less. The mass ratio may be 0.1 or more, 0.5 or more, 1 or more, 1.5 or more, 2 or more, 2.2 or more, 2.4 or more, 2.6 or more, 2.8 or more, 3 or more, 3.2 or more, 3.4 or more, 3.6 or more, 3.8 or more, 4 or more, 4.2 or more, 4.4 or more, 4.6 or more, or 4.8 or more. The mass ratio may be 0.1 to 20 from these viewpoints. The mass ratio may be 5 or more, 5.2 or more, 5.4 or more, 5.6 or more, 5.8 or more, 6 or more, 6.2 or more, or 6.4 or more.

### [Non-Ionic Polymer]

The polishing liquid according to the present embodiment may further contain a non-ionic polymer (non-ionic polymer). The “non-ionic polymer” is a polymer that does not have a cationic group, a group that can be ionized into a cationic group, an anionic group, and a group that can be ionized into an anion in a main chain thereof or a side chain thereof. Examples of the cationic group include an amino group, an imino group, and a cyano group, and examples of the anionic group include a carboxy group, a phosphoric acid group, and a sulfonic acid group. The non-ionic polymer has a plurality of structural units (repeating units) of the same type. By using the non-ionic polymer, the abrasive grains are easily dispersed, and excellent polishing selectivity of silicon oxide with respect to silicon nitride is easily obtained.

Examples of the non-ionic polymer include a glycerin-based polymer, a polyoxyalkylene compound, polyvinyl alcohol, and polyvinylpyrrolidone.

Examples of the glycerin-based polymer include polyglycerol and a polyglycerol derivative. Examples of the polyglycerol derivative include polyoxyalkylene polyglyceryl ether, polyglycerol fatty acid ester, and polyglycerol alkyl ether.

The polyoxyalkylene compound is a compound having a polyoxyalkylene chain. Examples of the polyoxyalkylene compound include a polyalkylene glycol and a polyoxyalkylene derivative.

Examples of the polyalkylene glycol include polyethylene glycol, polypropylene glycol, and polybutylene glycol.

Examples of the polyoxyalkylene derivative include a compound in which a substituent is introduced into polyalkylene glycol, and a compound in which polyalkylene oxide is added to an organic compound. Examples of the substituent include an alkyl ether group, an alkyl phenyl ether group, a phenyl ether group, a styrenated phenyl ether group, a fatty acid ester group, and a glycol ester group. Examples of the polyoxyalkylene derivative include an aromatic polyoxyalkylene compound, polyoxyalkylene alkyl ether, polyoxyalkylene sorbitan fatty acid ester, and polyoxyalkylene fatty acid ester.

The aromatic polyoxyalkylene compound is a compound in which a substituent having an aromatic ring is introduced into a polyoxyalkylene chain. The aromatic ring may be directly bonded or not be directly bonded to a polyoxyalkylene chain. The aromatic ring may be a monocyclic or polycyclic. The aromatic polyoxyalkylene compound may have a structure in which a plurality of polyoxyalkylene chains are bonded via a substituent having an aromatic ring. From the viewpoint of easily obtaining excellent polishing selectivity of silicon oxide with respect to silicon nitride, the polyoxyalkylene chain may be at least one selected from the group consisting of a polyoxyethylene chain, a polyoxypropylene chain, and a polyoxyethylene-polyoxypropylene chain.

In a case where the aromatic ring is positioned at the terminal of the aromatic polyoxyalkylene compound, examples of the substituent having an aromatic ring include an aryl group. Examples of the aryl group include monocyclic aromatic groups such as a phenyl group, a benzyl group, a tolyl group, and a xylyl group; and polycyclic aromatic group such as a naphthyl group, and such aromatic groups may further have a substituent. Examples of the substituent introduced into the aromatic group include an alkyl group, a vinyl group, an allyl group, an alkenyl group, an alkynyl group, and a styrene group, and from the viewpoint of easily obtaining excellent polishing selectivity of silicon oxide with respect to silicon nitride, the substituent may be an alkyl group or a styrene group.

In a case where the aromatic ring is positioned in the main chain of the aromatic polyoxyalkylene compound, examples of the substituent having an aromatic ring include an arylene group. Examples of the arylene group include monocyclic aromatic groups such as a phenylene group, a tolylene group, and a xylylene group; and polycyclic aromatic group such as a naphthylene group, and these aromatic groups may further have a substituent. Examples of the substituent introduced into the aromatic group include an alkyl group, a vinyl group, an allyl group, an alkenyl group, an alkynyl group, and a styrene group.

From the viewpoint of easily obtaining excellent polishing selectivity of silicon oxide with respect to silicon nitride, the aromatic polyoxyalkylene compound may contain at least one selected from the group consisting of a compound represented by General Formula (I) below and a compound represented by General Formula (II) below.

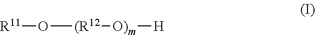

[In Formula (I), R11 represents an aryl group which may have a substituent, R12 represents an alkylene group having 1 to 5 carbon atoms which may have a substituent, and “m” represents an integer of 10 or more.]

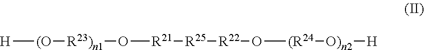

[In Formula (II), R21 and R22 each independently represent an arylene group which may have a substituent, R23, R24, and R25 each independently represent an alkylene group having 1 to 5 carbon atoms which may have a substituent, and “n1” and “n2” each independently represent an integer of 15 or more.]

Formula (I) may satisfy at least one of the following conditions from a viewpoint of easily obtaining excellent polishing selectivity of silicon oxide with respect to silicon nitride.
R11 may be the above-described aryl group exemplified as a substituent having an aromatic ring, may be a phenyl group into which a styrene group or an alkyl group is introduced as a substituent, or may be a phenyl group into which a plurality of (for example, two) styrene groups are introduced as substituents.
R12 may be an alkylene group having 1 to 3 carbon atoms or an ethylene group.
m may be 15 or more, or 30 or more.
m may be 20,000 or less, 10,000 or less, 5000 or less, or 1000 or less.

Examples of the aromatic polyoxyalkylene compound represented by Formula (I) include polyoxyalkylene phenyl ether, polyoxyalkylene alkyl phenyl ether, polyoxyalkylene styrenated phenyl ether, polyoxyalkylene distyrenated phenyl ether, polyoxyalkylene cumyl phenyl ether, and polyoxyalkylene benzyl ether. Specific examples of the aromatic polyoxyalkylene compound represented by Formula (I) include polyoxyethylene alkyl phenyl ether, polyoxyethylene nonylpropenyl phenyl ether, polyoxyethylene phenyl ether, polyoxyethylene styrenated phenyl ether, polyoxyethylene distyrenated phenyl ether, polyoxypropylene phenyl ether, polyoxyethylene cumyl phenyl ether, and polyoxyethylene benzyl ether.

Examples of the aromatic polyoxyalkylene compound represented by Formula (II) include polyoxyalkylene bisphenol ether. Specific examples of the aromatic polyoxyalkylene compound represented by Formula (II) include 2,2-bis(4-polyoxyethylene oxyphenyl) propane.

From the viewpoint of easily obtaining excellent polishing selectivity of silicon oxide with respect to silicon nitride, the non-ionic polymer may contain at least one selected from the group consisting of a glycerin-based polymer and a polyoxyalkylene compound and may contain a glycerin-based polymer and a polyoxyalkylene compound. From the viewpoint of easily obtaining excellent polishing selectivity of silicon oxide with respect to silicon nitride, the polyoxyalkylene compound may contain an aromatic polyoxyalkylene compound, may contain at least one selected from the group consisting of polyoxyalkylene styrenated phenyl ether and polyoxyalkylene distyrenated phenyl ether, and may contain at least one selected from the group consisting of polyoxyethylene styrenated phenyl ether and polyoxyethylene distyrenated phenyl ether.

The polishing liquid of the present embodiment may contain a non-ionic polymer having a weight average molecular weight described below from the viewpoint of easily obtaining excellent polishing selectivity of silicon oxide with respect to silicon nitride. The weight average molecular weight of the non-ionic polymer may be 100 or more, 200 or more, 300 or more, 500 or more, 600 or more, 700 or more, and 750 or more. The weight average molecular weight of the non-ionic polymer may be 100000 or less, 50000 or less, 10000 or less, 5000 or less, 3000 or less, 1000 or less, 800 or less, and 750 or less. From these viewpoints, the weight average molecular weight of the non-ionic polymer may be 100 to 100000.

The weight average molecular weight of the non-ionic polymer can be measured, for example, by gel permeation chromatography (GPC) using a calibration curve of polystyrene standards under the following conditions.
Instrument used: Hitachi L-6000 Model [manufactured by Hitachi, Ltd.]
Column: GELPACK GL-R420+GELPACK GL-R430+GELPACK GL-R440 [manufactured by Hitachi High-Tech Co., Ltd., trade names, three in total]
Eluent: Tetrahydrofuran
Measurement temperature: 40 C
Flow rate: 1.75 mL/min
Detector: L-3300RI [manufactured by Hitachi, Ltd.]

The content of the non-ionic polymer may be in the following range based on the total mass of the polishing liquid from a viewpoint of easily obtaining excellent polishing selectivity of silicon oxide with respect to silicon nitride. The content of the non-ionic polymer may be 0.001 mass % or more, 0.005 mass % or more, 0.008 mass % or more, 0.01 mass % or more, 0.03 mass % or more, 0.05 mass % or more, 0.08 mass % or more, 0.1 mass % or more, more than 0.1 mass %, 0.3 mass % or more, 0.4 mass % or more, or 0.5 mass % or more. The content of the non-ionic polymer may be 10 mass % or less, 5 mass % or less, 1 mass % or less, less than 1 mass %, 0.8 mass % or less, 0.7 mass % or less, 0.6 mass % or less, 0.55 mass % or less, or 0.5 mass % or less. The content of the non-ionic polymer may be 0.001 to 10 mass % from these viewpoints.

The content of the glycerin-based polymer may be in the following range based on the total mass of the polishing liquid from a viewpoint of easily obtaining excellent polishing selectivity of silicon oxide with respect to silicon nitride. The content of the glycerin-based polymer may be 0.001 mass % or more, 0.005 mass % or more, 0.008 mass % or more, 0.01 mass % or more, 0.03 mass % or more, 0.05 mass % or more, 0.08 mass % or more, 0.1 mass % or more, more than 0.1 mass %, 0.3 mass % or more, 0.4 mass % or more, or 0.5 mass % or more. The content of the glycerin-based polymer may be 10 mass % or less, 5 mass % or less, 1 mass % or less, less than 1 mass %, 0.8 mass % or less, 0.7 mass % or less, 0.6 mass % or less, or 0.5 mass % or less. The content of the glycerin-based polymer may be 0.001 to 10 mass % from these viewpoints.

When the non-ionic polymer contains a glycerin-based polymer, the content of the glycerin-based polymer in the non-ionic polymer may be 50 mass % or more, more than 50 mass %, 80 mass % or more, 90 mass % or more, 95 mass % or more, 98 mass % or more, or 99 mass % or more based on the total mass of the non-ionic polymer from a viewpoint of easily obtaining excellent polishing selectivity of silicon oxide with respect to silicon nitride. The non-ionic polymer may be substantially composed of a glycerin-based polymer (substantially 100 mass % of the non-ionic polymer may be a glycerin-based polymer).

The content of the non-ionic polymer with respect to 100 parts by mass of the abrasive grains may be in the following range from a viewpoint of easily obtaining excellent polishing selectivity of silicon oxide with respect to silicon nitride. The content of the non-ionic polymer with respect to 100 parts by mass of the abrasive grains may be 2000 parts by mass or less, 1500 parts by mass or less, 1200 parts by mass or less, 1100 parts by mass or less, or 1000 parts by mass or less. The content of the non-ionic polymer with respect to 100 parts by mass of the abrasive grains may be 1 part by mass or more, 10 parts by mass or more, 100 parts by mass or more, 500 parts by mass or more, 700 parts by mass or more, 900 parts by mass or more, or 1000 parts by mass or more. The content of the non-ionic polymer with respect to 100 parts by mass of the abrasive grains may be 1 to 2000 parts by mass from these viewpoints.

The content of the non-ionic polymer with respect to 100 parts by mass of the acid component A may be in the following range from a viewpoint of easily obtaining excellent polishing selectivity of silicon oxide with respect to silicon nitride. The content of the non-ionic polymer with respect to 100 parts by mass of the acid component A may be 2000 parts by mass or less, 1500 parts by mass or less, 1000 parts by mass or less, 900 parts by mass or less, 800 parts by mass or less, or 700 parts by mass or less. The content of the non-ionic polymer with respect to 100 parts by mass of the acid component A may be 1 part by mass or more, 10 parts by mass or more, 50 parts by mass or more, 100 parts by mass or more, 120 parts by mass or more, 140 parts by mass or more, or 150 parts by mass or more. The content of the non-ionic polymer with respect to 100 parts by mass of the acid component A may be 1 to 2000 parts by mass from these viewpoints.

### [Base Component]

The polishing liquid according to the present embodiment may further contain a base component. The polishing liquid containing the acid component A further contains a base component, whereby a pH buffering effect tends to be obtained, and therefore the pH of the polishing liquid is easily stabilized. Therefore, excellent polishing selectivity of silicon oxide with respect to silicon nitride is easily obtained. Examples of the base component include a compound having an amino group (a heterocyclic amine, an alkylamine, or the like), ammonia, and sodium hydroxide. When an isoelectric point (pI) of an amphoteric compound exceeds 4.5, the compound is treated as a base component. Examples of the compound having an isoelectric point of more than 4.5 include glycine. The base component may contain a compound having an amino group, may contain a fatty acid amine, or may contain a heterocyclic amine from a viewpoint of further easily stabilizing the pH of the polishing liquid.

Examples of the fatty acid amine include: a monoamine such as methylamine, ethylamine, or trishydroxymethylaminomethane; a diamine such as dimethylamine or diethylamine; and a triamine such as trimethylamine or triethylamine. The base component may contain a monoamine or trishydroxymethylaminomethane from a viewpoint of easily obtaining excellent polishing selectivity of silicon oxide with respect to silicon nitride.

The heterocyclic amine is an amine having at least one heterocyclic ring. Examples of the heterocyclic amine include compounds having a pyrrolidine ring, a pyrrole ring, an imidazole ring, a pyrazole ring, an oxazole ring, a thiazole ring, a pyridine ring, a pyrazine ring, a pyrimidine ring, a pyridazine ring, a triazine ring, a tetrazine ring, and the like. The base component may contain an imidazole compound (a compound having an imidazole ring) or may contain an imidazole from a viewpoint of easily obtaining excellent polishing selectivity of silicon oxide with respect to silicon nitride.

The content of the base component may be in the following range based on the total mass of the polishing liquid from a viewpoint of easily obtaining excellent polishing selectivity of silicon oxide with respect to silicon nitride. The content of the base component may be 0.001 mass % or more, 0.005 mass % or more, 0.01 mass % or more, 0.03 mass % or more, 0.05 mass % or more, 0.07 mass % or more, or 0.08 mass % or more. The content of the base component may be 3 mass % or less, 1 mass % or less, 0.8 mass % or less, 0.6 mass % or less, 0.5 mass % or less, 0.4 mass % or less, 0.3 mass % or less, or 0.2 mass % or less. The content of the base component may be 0.001 to 3 mass % from these viewpoints.

When the polishing liquid according to the present embodiment contains the acid component A and the base component, a mass ratio of the content of the base component with respect to the content of the acid component A (content of base component/content of acid component A) may be 0.1 or more, 0.3 or more, 0.5 or more, 0.8 or more, 0.9 or more, 1 or more, 1.1 or more, 1.2 or more, 1.3 or more, 1.4 or more, 1.5 or more, 1.6 or more, 1.7 or more, 1.8 or more, 1.9 or more, or 2 or more from a viewpoint of easily obtaining excellent polishing selectivity of silicon oxide with respect to silicon nitride. The mass ratio may be 10 or less, 8 or less, 6 or less, 5 or less, 4 or less, 3.5 or less, 3 or less, 2.9 or less, 2.8 or less, 2.7 or less, 2.6 or less, or 2.5 or less. The mass ratio may be 0.1 to 10 from these viewpoints.

### [Other Additives]

The polishing liquid according to the present embodiment may contain an optional additive (excluding a compound corresponding to the acid component A, the non-ionic polymer, or the base component described above). Examples of the optional additive include an oxidant (hydrogen peroxide or the like), a dispersant (triethylolethane or the like), an alcohol (3-methoxy-3-methyl-1-butanol or the like), and an acid component other than the acid component A (an acid component having a carboxy group or the like). The polishing liquid according to the present embodiment may contain a cationic polymer or does not have to contain a cationic polymer. The content of the cationic polymer may be less than 0.0001 mass % based on the total mass of the polishing liquid.

### (Water)

The polishing liquid of the present embodiment can contain water. Examples of water include deionized water and ultrapure water. The content of the water may correspond to the remaining of the polishing liquid from which the contents of other constituent components are removed.

(pH)

The pH of the polishing liquid according to the present embodiment is more than 4.5 from a viewpoint of obtaining excellent polishing selectivity of silicon oxide with respect to silicon nitride. The pH of the polishing liquid may be 4.6 or more, 4.7 or more, 4.8 or more, 4.9 or more, 5 or more, more than 5, or 5.1 or more from a viewpoint of easily obtaining excellent polishing selectivity of silicon oxide with respect to silicon nitride. The pH of the polishing liquid may be 12 or less, 11 or less, 10 or less, 9 or less, 8.8 or less, 8.6 or less, 8.4 or less, 8.2 or less, 8 or less, less than 8, 7.8 or less, 7.6 or less, 7.5 or less, less than 7.5, 7.4 or less, 7.2 or less, 7 or less, less than 7, 6.8 or less, 6.6 or less, 6.5 or less, less than 6.5, 6.4 or less, 6.2 or less, 6 or less, or less than 6 from a viewpoint of easily obtaining excellent polishing selectivity of silicon oxide with respect to silicon nitride. The pH of the polishing liquid may be 5.2 or more, 5.3 or more, 5.4 or more, 5.5 or more, 5.6 or more, 5.7 or more, 5.8 or more, 5.9 or more, 6 or more, or more than 6. The pH of the polishing liquid is defined as pH at a liquid temperature of 25° C.

The pH of the polishing liquid of the present embodiment can be measured by using a pH meter (for example, Model D-51 manufactured by HORIBA, Ltd.). For example, after performing 3-point calibration of the pH meter using a phthalate pH buffer solution (pH: 4.01), a neutral phosphate pH buffer solution (pH: 6.86), and a borate pH buffer solution (pH: 9.18) as standard buffer solutions, an electrode of the pH meter is placed in the polishing liquid for 3 minutes or longer, and the value after stabilization is measured. The liquid temperature of both the standard buffer solution and the polishing liquid are set to 25° C.

The polishing liquid according to the present embodiment may be stored as a one-pack type polishing liquid containing at least abrasive grains containing a hydroxide of a tetravalent metal element and the acid component A, or may be stored as a multi-component (for example, two-pack type) polishing liquid set in which constituent components of the above-described polishing liquid are divided into a slurry and an additive liquid such that the slurry (first liquid) and the additive liquid (second liquid) are mixed to obtain the above-described polishing liquid. The slurry contains, for example, at least abrasive grains and water. The additive liquid contains, for example, at least the acid component A and water. The base component, other additives, and the like are preferably contained in the additive liquid out of the slurry and the additive liquid. The constituent components of the above-described polishing liquid may be stored as a polishing liquid set divided into three or more components.

In the aforementioned polishing liquid set, the slurry and the additive liquid are mixed immediately before polishing or during polishing to prepare the polishing liquid. A one-pack type polishing liquid may be stored as a stock solution for a polishing liquid with a reduced water content and used by dilution with water during the polishing. The multi-pack type polishing liquid set may be stored as a stock solution for a slurry and a stock solution for an additive liquid with a reduced water content, and used by dilution with water during the polishing.

A method for manufacturing the polishing liquid according to the present embodiment includes a mixing step of mixing abrasive grains and the acid component A. The mixing step may be a step of obtaining the polishing liquid by mixing the abrasive grains and the acid component A together. The mixing step may be a step of obtaining the polishing liquid by mixing, in addition to the abrasive grains and the acid component A, a component other than the abrasive grains and the acid component A (for example, a non-ionic polymer) together.

### <Polishing Method>

A polishing method of the present embodiment includes a polishing step of polishing a surface to be polished by using the polishing liquid of the present embodiment. In the polishing step, the material to be polished of the surface to be polished is polished so as to be removed. The surface to be polished may contain silicon oxide and silicon nitride. That is, the surface to be polished may have a portion to be polished composed of silicon oxide and a portion to be polished composed of silicon nitride. The polishing step may be a step of polishing a surface to be polished containing silicon oxide and silicon nitride by using the polishing liquid of the present embodiment so as to selectively remove silicon oxide with respect to silicon nitride. In the polishing liquid used in the polishing step, the polishing liquid may be the aforementioned one-pack type polishing liquid or may be a polishing liquid obtained by mixing a slurry and an additive liquid in the aforementioned polishing liquid set.

In the polishing step, for example, while a surface to be polished of a base substrate is pressed on a polishing pad (polishing cloth) of a polishing platen, the aforementioned polishing liquid is supplied between the surface to be polished and the polishing pad, and the base substrate and the polishing platen are relatively moved to polish the surface to be polished.

As the base substrate that is to be polished, a substrate to be polished or the like is exemplified. As the substrate to be polished, for example, a base substrate in which a material to be polished is formed on a substrate for semiconductor element production (for example, a semiconductor substrate in which an STI pattern, a gate pattern, a wiring pattern, or the like is formed) is exemplified. The portion to be polished of the substrate to be polished may contain silicon oxide and silicon nitride. The portion to be polished may be in the form of a film (film to be polished) or may be a silicon oxide film, a silicon nitride film, or the like.

A portion to be polished may be a silicon carbonitride film. The silicon carbonitride film is a film in which silicon nitride is doped with a carbon atom. It can be confirmed by Raman spectroscopy that the portion to be polished is a silicon carbonitride film.

In the polishing method of the present embodiment, as a polishing apparatus, it is possible to use a common polishing apparatus which has a holder capable of holding a base substrate having a surface to be polished and a polishing platen to which a polishing pad can be pasted. A motor or the like in which the number of rotations can be changed may be attached to each of the holder and the polishing platen. As the polishing apparatus, for example, a polishing apparatus: Reflexion manufactured by Applied Materials, Inc. can be used.

As the polishing pad, common unwoven cloth, a foamed body, an unfoamed body, and the like can be used. As the material of the polishing pad, it is possible to use a resin such as polyurethane, an acrylic resin, polyester, an acrylic-ester copolymer, polytetrafluoroethylene, polypropylene, polyethylene, poly-4-methylpentene, cellulose, cellulose ester, polyamide (for example, Nylon (trade name) and aramid), polyimide, polyimidamide, a polysiloxane copolymer, an oxirane compound, a phenolic resin, polystyrene, polycarbonate, or an epoxy resin.

Although the polishing conditions are not limited, a rotation rate (rotation number) of a polishing surface plate may be 200 min-1 or less to prevent a base substrate from flying off, and a polishing pressure (processing load) applied to the base substrate may be 100 kPa or less from a viewpoint of sufficiently suppressing generation of polishing flaws. During polishing, the polishing liquid may be continuously supplied to a polishing pad by a pump or the like. Although the amount of the polishing liquid supplied is not limited, a surface of the polishing pad may be constantly covered with the polishing liquid.

After polishing is completed, the base substrate may be thoroughly washed in running water to remove particles adhering to the base substrate. For washing, in addition to pure water, a chemical solution for washing such as diluted hydrofluoric acid or ammonia water may be used, and a brush may be used in order to improve washing efficiency. In addition, after washing, water droplets adhering to the base substrate may be removed using a spin dryer or the like, and then the base substrate may be dried.

The polishing liquid and the polishing method according to the present embodiment may be applied not only to a film-like object to be polished but also to various substrates formed of glass, silicon, SiC, SiGe, Ge, GaN, GaP, GaAs, sapphire, plastic, and the like.

The polishing liquid and the polishing method according to the present embodiment can be used not only in manufacturing a semiconductor device but also in an image display device such as a TFT liquid crystal or an organic EL; an optical component such as a photomask, a lens, a prism, an optical fiber, or a single crystal scintillator; an optical element such as an optical switching element or an optical waveguide; a light emitting element such as a solid laser or a blue laser LED; and a magnetic storage device such as a magnetic disk or a magnetic head.

### <Manufacturing Method and the Like>

A method for manufacturing a component according to the present embodiment includes a component preparation step of obtaining a component using a base substrate (member to be polished) polished by the polishing method according to the present embodiment. The component according to the present embodiment is a component obtained by the method for manufacturing a component according to the present embodiment. The component according to the present embodiment is not particularly limited, and may be an electronic component (for example, a semiconductor component such as a semiconductor package), a wafer (for example, a semiconductor wafer), or a chip (for example, a semiconductor chip). As an aspect of the method for manufacturing a component according to the present embodiment, in a method for manufacturing an electronic component according to the present embodiment, an electronic component is obtained using a base substrate polished by the polishing method according to the present embodiment. As an aspect of the method for manufacturing a component according to the present embodiment, in a method for manufacturing a semiconductor component according to the present embodiment, a semiconductor component (for example, a semiconductor package) is obtained using a base substrate polished by the polishing method according to the present embodiment. The method for manufacturing a component according to the present embodiment may include a polishing step of polishing a base substrate by the polishing method according to the present embodiment before the component preparation step.

The method for manufacturing a component according to the present embodiment may include, as an aspect of the component preparation step, a segmentation step of segmenting a base substrate (member to be polished) polished by the polishing method according to the present embodiment. The segmentation step may be, for example, a step of dicing a wafer (for example, a semiconductor wafer) polished by the polishing method according to the present embodiment to obtain a chip (for example, a semiconductor chip). As an aspect of the method for manufacturing a component according to the present embodiment, the method for manufacturing an electronic component according to the present embodiment may include a step of obtaining an electronic component (for example, a semiconductor component) by segmenting a base substrate polished by the polishing method according to the present embodiment. As an aspect of the method for manufacturing a component according to the present embodiment, the method for manufacturing a semiconductor component according to the present embodiment may include a step of obtaining a semiconductor component (for example, a semiconductor package) by segmenting a base substrate polished by the polishing method according to the present embodiment.

The method for manufacturing a component according to the present embodiment may include a connection step of connecting (for example, electrically connecting) a base substrate (member to be polished) polished by the polishing method according to the present embodiment and another body to be connected as an aspect of the component preparation step. The body to be connected to the base substrate polished by the polishing method according to the present embodiment is not particularly limited, and may be a base substrate polished by the polishing method according to the present embodiment, or may be a body to be connected different from the base substrate polished by the polishing method according to the present embodiment.

In the connection step, the base substrate and the body to be connected may be directly connected (connected in a state where the base substrate and the body to be connected are in contact with each other), or the base substrate and the body to be connected may be connected via another member (conductive member or the like). The connection step can be performed before the segmentation step, after the segmentation step, or before and after the segmentation step.

The connection step may be a step of connecting a surface to be polished of the base substrate polished by the polishing method according to the present embodiment and the body to be connected, or may be a step of connecting a connection surface of the base substrate polished by the polishing method according to the present embodiment and a connection surface of the body to be connected. The connection surface of the base substrate may be the surface to be polished, which is polished by the polishing method according to the present embodiment. By the connection step, a connection body including a base substrate and a body to be connected can be obtained. In the connection step, when the connection surface of the base substrate has a metal portion, the body to be connected may be brought into contact with the metal portion. In the connection step, when the connection surface of the base substrate has the metal portion and the connection surface of the body to be connected has the metal portion, the metal portions may be brought into contact with each other. The metal portion may contain copper.

A device (for example, an electronic device such as a semiconductor device) according to the present embodiment includes at least one selected from the group consisting of a base substrate polished by the polishing method according to the present embodiment and a component according to the present embodiment.

### EXAMPLES

Hereinafter, the present disclosure will be described in more detail with reference to examples. However, the present disclosure is not limited to these examples without departing from the technical idea of the present disclosure. For example, the type of materials of the polishing liquid and the blending ratio thereof may be types and ratios other than the types and ratios described in the present examples, and the composition and the structure of the object to be polished may also be compositions and structures other than the compositions and the structures described in the present examples.

### <Preparation of Abrasive Grains>

350 g of an aqueous 50% by mass Ce(NH₄)₂(NO₃)6 solution (trade name: CAN50 liquid manufactured by Nihon Kagaku Sangyo Co., Ltd.) was mixed with 7825 g of pure water to obtain a solution. Next, while stirring this solution, 750 g of an aqueous imidazole solution (10% by mass aqueous solution, 1.47 mol/L) was added dropwise thereto at a mixing rate of 5 mL/min to obtain a precipitate containing cerium hydroxide. The cerium hydroxide was synthesized at a temperature of 25° C. and a stirring speed of 400 min-1. The stirring was carried out using a 3-blade pitch paddle with a total blade section length of 5 cm.

The obtained precipitate (precipitate containing cerium hydroxide) was subjected to centrifugal separation (4000 min-1, for 5 minutes), and then subjected to solid-liquid separation with removal of a liquid phase by decantation. 10 g of particles obtained by solid-liquid separation and 990 g of water were mixed, and then the particles were dispersed in the water by using an ultrasonic cleaner to prepare a cerium hydroxide slurry (content of abrasive grains: 1.0% by mass) containing abrasive grains containing cerium hydroxide.

### <Measurement of Average Particle Diameter>

When the average particle diameter of the abrasive grains (the abrasive grains containing cerium hydroxide) in the cerium hydroxide slurry was measured using trade name: N5 manufactured by Beckman Coulter, Inc., a value of 3 nm was obtained. The measurement method is as follows. First, about 1 mL of a measuring sample (cerium hydroxide slurry, aqueous dispersion liquid) containing 1.0 mass % of abrasive grains was poured into a 1-cm square cell, and the cell was set in N5. Measurement was performed at 25° C. with the refractive index set to 1.333 and the viscosity set to 0.887 mPa·s as the measuring sample information of N5 software.

### <Structural Analysis of Abrasive Grains>

An adequate amount of the cerium hydroxide slurry was collected and dried in a vacuum, and thereby the abrasive grains were isolated, and then, sufficient washing was performed with pure water to obtain a sample. When the obtained sample was measured by an FT-IR ATR method, a peak based on nitrate ion (NO₃⁻) was observed in addition to a peak based on hydroxide ion (OH⁻). Furthermore, when the same sample was measured by XPS (N-XPS) for nitrogen, a peak based on nitrate ion was observed while no peak based on NH₄⁺ was observed. These results confirmed that the abrasive grains contained in the cerium hydroxide slurry at least partially contained particles having nitrate ion bonded to cerium element. Furthermore, since particles having hydroxide ion bonded to cerium element were contained at least in a portion of the abrasive grains, it was confirmed that the abrasive grains contained cerium hydroxide. These results confirmed that the cerium hydroxide contained a hydroxide ion bonded to a cerium element.

### <Preparation of CMP Polishing Liquid>

### Example 1

By mixing 100 g of an additive liquid containing 1.6 mass % of sulfanilic acid, 5 mass % of polyglycerin [non-ionic polymer, manufactured by Sakamoto Yakuhin Kogyo Co., Ltd., trade name: polyglycerin #750, weight average molecular weight: 750, average polymerization degree: 10], 1.4 mass % of imidazole, and water (balance), 850 g of water, and 50 g of the above-described cerium hydroxide slurry, a CMP polishing liquid containing 0.05 mass % of abrasive grains containing a cerium hydroxide, 0.16 mass % of sulfanilic acid, 0.5 mass % of polyglycerin, and 0.14 mass % of imidazole was prepared.

### Examples 2 to 15 and Comparative Examples 1 and 2

A CMP polishing liquid having the composition illustrated in Table 1 was prepared in a similar manner to Example 1 except that the types and contents of the acid component and the base component were changed. Note that the acid components A1 to A8 and the base components B1 to B2 in the table are as follows.

### [Acid Component]

A1: sulfanilic acid
A2:3-pyridine sulfonic acid
A3: sulfamic acid
A4: benzenesulfonic acid
A5:2,5-dimethylbenzenesulfonic acid
A6: isoquinoline-5-sulfonic acid
A7:4-aminobenzoic acid
A8: acetic acid

### [Base Component]

B1: imidazole
B2: tris-hydroxymethylaminomethane

### <Evaluation>

### (pH of CMP Polishing Liquid)

The pH of the CMP polishing liquid was measured under the following conditions. Results thereof are illustrated in Table 1.
Measurement temperature: 25° C.
Measuring device: Model D-51 manufactured by HORIBA, Ltd.

Measurement method: Three-point calibration was performed using a standard buffer solution (phthalate pH buffer, pH: 4.01 (25° C.);

neutral phosphate pH buffer, pH: 6.86 (25° C.); borate pH buffer, pH: 9.18 (25° C.)). Thereafter, an electrode was put in the CMP polishing liquid, and pH when the CMP polishing liquid was stabilized after an elapse of three minutes or more was measured by the above-described measuring device.

### (Particle Diameter of Abrasive Grains)

When the average particle diameter of the abrasive grains (the abrasive grains containing cerium hydroxide) in the CMP polishing liquids of Examples 1 to 15 and Comparative Examples 1 and 2 was measured under the following conditions, a value of 12 nm was obtained.
Measurement temperature: 25° C.
Measuring apparatus: trade name: DelsaMax PRO manufactured by Beckman Coulter, Inc.

Measurement method: About 0.5 mL of the CMP polishing liquid was poured in a cell for measurement (disposable micro cuvette) having a size of 12.5 mm×12.5 mm×45 mm (height) and then the cell was set in the apparatus. Measurement was performed at 25° C. with the refractive index set to 1.333 and the viscosity set to 0.887 mPa·s as the measuring sample information, and the value displayed as Unimodal Size Mean (cumulant diameter) was read off.

### (Polishing Rate)

The following blanket wafer was polished by using the aforementioned CMP polishing liquid under the following CMP polishing conditions.

### [Blanket Wafer]

Blanket wafer that has a silicon oxide film having a thickness of 1000 nm on a silicon substrate (diameter: 300 mm)

Blanket wafer that has a silicon nitride film having a thickness of 250 nm on a silicon substrate (diameter: 300 mm)

### [CMP Polishing Conditions]

Polishing apparatus: FREX 300X (manufactured by Ebara Co., Ltd.)
Flow rate of CMP polishing liquid: 200 mL/min
Substrate to be polished: Aforementioned blanket wafer
Polishing pad: Foamed polyurethane having closed pores (Model No. IC1010 manufactured by ROHM AND HAAS ELECTRONIC MATERIALS CMP INC.)
Polishing pressure: 20.7 kPa (3.0 psi)
Relative speed between substrate to be polished and polishing platen: 100.5 m/min
Polishing time: 30 seconds

Washing of wafer: After a CMP treatment, washing was performed with water while applying an ultrasonic wave, and then drying was performed with a spin dryer.

### [Calculation of Polishing Rate and Polishing Rate Ratio]

65 film thicknesses of the films to be polished (the silicon oxide film and the silicon nitride film) before and after polishing were measured by using a light interference type film thickness measuring apparatus (device name: F80) manufactured by Filmetrics Japan, Inc. The measurement of 65 film thicknesses was performed at positions of 149 mm, 148 mm, 147 mm, and 145 mm, positions at every 5 mm between 145 mm and −145 mm (140 mm, 135 mm, . . . , −135 mm, and −140 mm), and positions of −145 mm, −147 mm, −148 mm, and −149 mm on the straight line including the center of the wafer on the basis of the center of the wafer (the distance opposite to the plus distance is described as the minus distance on the basis of the center of the wafer). A change amount in film thickness was calculated using an average value of 65 film thicknesses. The polishing rates for materials to be polished (a polishing rate RO of silicon oxide and a polishing rate RN of silicon nitride) were calculated by the following formula on the basis of a change amount of the film thickness and the polishing time. Furthermore, a polishing rate ratio (RO/RN) of the polishing rate RO of silicon oxide to the polishing rate RN of silicon nitride was calculated. The results are shown in Table 1.

$$Polishing rate [ Å / min ] = ( Film thickness [ Å ] before polishing - Film thickness [ Å ] after polishing ) / Polishing time [ min ]$$

TABLE 1

| | Acid component | | Base component | | | Polishing rate | | Polishing |
|---|---|---|---|---|---|---|---|---|
| | | Content | | Content | | [Å/min] | | rate ratio |
| | Type | [mass %] | Type | [mass %] | pH | RO | RN | RO/RN |
| Example 1 | A1 | 0.16 | B1 | 0.08 | 6.3 | 2449 | 17 | 144.1 |
| Example 2 | A1 | 0.16 | B2 | 0.11 | 5.1 | 2630 | 1 | 2630.0 |
| Example 3 | A1 | 0.24 | B1 | 0.10 | 5.8 | 2668 | 0 | — |
| Example 4 | A1 | 0.24 | B1 | 0.12 | 6.4 | 2344 | 40 | 58.6 |
| Example 5 | A1 | 0.24 | B2 | 0.17 | 5.2 | 2670 | 12 | 222.5 |
| Example 6 | A1 | 0.24 | B2 | 0.18 | 6.3 | 2496 | 103 | 24.2 |
| Example 7 | A1 | 0.32 | B1 | 0.14 | 6.1 | 2121 | 7 | 302.9 |
| Example 8 | A1 | 0.32 | B1 | 0.15 | 6.4 | 2118 | 23 | 92.1 |
| Example 9 | A1 | 0.32 | B2 | 0.23 | 5.4 | 1902 | 7 | 271.6 |
| Example 10 | A1 | 0.32 | B2 | 0.23 | 6.4 | 2108 | 70 | 30.1 |
| Example 11 | A2 | 0.24 | B1 | 0.11 | 5.9 | 2650 | 12 | 220.8 |
| Example 12 | A3 | 0.24 | B1 | 0.19 | 6.0 | 2398 | 22 | 109.0 |
| Example 13 | A4 | 0.24 | B1 | 0.11 | 5.9 | 2432 | 6 | 405.3 |
| Example 14 | A5 | 0.16 | B1 | 0.06 | 6.1 | 2024 | 6 | 337.3 |
| Example 15 | A6 | 0.08 | B1 | 0.03 | 6.1 | 1018 | 6 | 169.7 |
| Comparative | A7 | 0.19 | B1 | 0.10 | 6.2 | 10 | 3 | 3.2 |
| Example 1 | | | | | | | | |
| Comparative | A8 | 0.083 | B1 | 0.10 | 6.2 | 1744 | 744 | 2.3 |
| Example 2 | | | | | | | | |

In Examples, it was confirmed that the polishing rate ratio (RO/RN) of the polishing rate RO of silicon oxide to the polishing rate RN of silicon nitride is 20 or more, and excellent polishing selectivity of silicon oxide with respect to silicon nitride is obtained.

1. A polishing liquid comprising: abrasive grains; and an acid component, wherein
the acid component comprises a compound (excluding sulfuric acid and a salt thereof) having at least one selected from the group consisting of a sulfo group and a sulfonate group, and
a pH is more than 4.5.

2. The polishing liquid according to claim 1, wherein the abrasive grains comprise a cerium hydroxide.

3. The polishing liquid according to claim 1, wherein the acid component comprises an aromatic compound having at least one selected from the group consisting of a sulfo group and a sulfonate group.

4. The polishing liquid according to claim 1, wherein the acid component comprises a compound having no amino group.

5. The polishing liquid according to claim 1, wherein the acid component comprises an aminosulfonic acid compound.

6. The polishing liquid according to claim 1, wherein the acid component comprises at least one selected from the group consisting of sulfanilic acid and a salt thereof.

7. The polishing liquid according to claim 1, wherein a content of the acid component is more than 0.2 mass % based on a total mass of the polishing liquid.

8. The polishing liquid according to claim 1, further comprising a nonionic polymer.

9. The polishing liquid according to claim 8, wherein the nonionic polymer comprises a glycerin-based polymer.

10. The polishing liquid according to claim 1, further comprising a base component.

11. The polishing liquid according to claim 1, which is used for polishing a surface to be polished comprising silicon oxide and silicon nitride.

12. A polishing method comprising a step of polishing a surface to be polished using the polishing liquid according to claim 1.

13. The polishing method according to claim 12, wherein the surface to be polished comprises silicon oxide and silicon nitride.

14. A method for manufacturing a component, the method comprising a step of obtaining the component using a member to be polished that has been polished by the polishing method according to claim 12.
